(19) United States
(12) Patent Application Publication
(10) Pub. No.: US 2006/0121195 A1
(43) Pub. Date: Jun. 8, 2006

(54) Plasma processing apparatus and method for manufacturing electrostatic chuck

(76) Inventors: Ryujiro Udo, Ushiku-shi (JP); Masatsugu Arai, Niihari-gun (JP); Masanori Kadotani, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/327,447

(22) Filed: Jan. 9, 2006

Related U.S. Application Data
(62) Division of application No. 10/377,825, filed on Mar. 4, 2003.

(30) Foreign Application Priority Data
Feb. 24, 2003 (JP) 2003-045775

(51) Int. Cl. C23C 14/32; C23C 16/00; C23C 14/00

(52) U.S. Cl. 427/248.1; 118/728; 204/192.1

(57) ABSTRACT

An electrostatic chuck comprising an insulating base 6, a plurality of conductive aluminum thin films 4a, 4b deposited on the surface of the base, and alumite films 2a, 2b formed by anodizing the surfaces of the conductive thin films 4a, 4b, wherein the conductive thin films 4a, 4b are each provided with a DC voltage of a different polarity so that a surface chucking a wafer 7 is electrostatically bipolar.

This application is a Divisional application of application Ser. No. 10/377,825, filed Mar. 4, 2003, the contents of which are incorporated herein by reference in their entirety.

### FIELD OF THE INVENTION

The present invention relates to a plasma processing apparatus. Especially, the present invention relates to a method for manufacturing a plasma processing apparatus comprising an electrostatic chuck having electrostatically bipolar electrodes disposed on the surface for chucking a wafer.

### DESCRIPTION OF THE RELATED ART

According to a prior art plasma processing apparatus utilizing an alumite (anodized aluminum) film as a chucking film of an electrostatic chuck, the base of the electrostatic chuck is formed of aluminum, the surface of which is anodized to create the alumite film constituting the chucking film (refer for example to Patent Document 1).

The advantages of the electrostatic chuck comprising alumite film as the chucking film compared to the electrostatic chuck comprising other substances such as sintered ceramic as the chucking film are that the chuck has a simple structure, is inexpensive to manufacture, and can be manufactured in a short time. However, the prior art electrostatic chuck utilizing alumite film as the chucking film has two large drawbacks. One drawback is that there is not much freedom allowed in designing the chuck, so it is easy to form a monopolar electrostatic chuck but is very difficult to form a bipolar electrostatic chuck. The other drawback is that the electrical or mechanical soundness of the alumite film is frequently degraded.

With regard to the former drawback, a monopolar electrostatic chuck used in plasma generates chucking force by utilizing the plasma as a conductor. Therefore, if by some reason the plasma disappears during the plasma processing, the chucking force is lost at once, and the wafer can no longer be held in position. However, in many cases, a gas such as helium is filled in the small gap formed between the wafer and the electrostatic chuck so as to enhance the heat conductivity between the chuck and the wafer. Therefore, when the chucking force disappears while gas pressure is loaded on the back surface of the wafer, the wafer may be pushed up from the electrostatic chuck by the gas pressure, by which the wafer may be dislocated and even damaged. This problem does not occur in a bipolar-type electrostatic chuck that maintains its chucking force regardless of the existence of plasma. Thus, it is very important to improve the freedom of design of the electrostatic chuck and to create a bipolar electrostatic chuck.

On the other hand, with regard to the latter problem, when defects such as cracks and chipping exist within the chucking film of the electrostatic chuck, problems such as degradation of withstand voltage and detachment of chucking film may occur. Especially, the alumite film often contains very fine cracks formed during formation, and these fine cracks may develop to larger cracks just by receiving a relatively small stress, so it is important that no tensile stress is loaded on the alumite film. However, if the electrostatic chuck comprises aluminum having a relatively large thermal expansion coefficient as base and comprises alumite having a relatively small thermal expansion coefficient as chucking film, a large thermal stress occurs near the interface between the base and the chucking film during temperature change since the thermal expansion coefficient of the base and the chucking film differ greatly. Especially when the temperature is rising, tensile stress generates in the chucking film, causing cracks to be formed and propagated in the chucking film. Thus, it is also important to suppress the formation and propagation of such cracks caused by thermal stress.

Patent Document 1

Japanese Patent Publication Laid-Open No. 5-160076

### SUMMARY OF THE INVENTION

The present invention aims at solving such problems of the prior art electrostatic chuck. The object of the present invention is to provide an inexpensive, easy-to-use and highly reliable plasma processing apparatus, and a method for manufacturing an inexpensive, easy-to-use and highly reliable electrostatic chuck.

The object of the present invention is achieved by a plasma processing apparatus comprising a plasma generating means for generating plasma within a vacuum processing chamber, and an electrostatic chuck for supporting on its upper surface a wafer to be subjected to processing; wherein a surface for chucking the wafer of the electrostatic chuck comprises an alumite film formed by anodizing aluminum, and the surface for chucking the wafer is electrostatically bipolar.

Furthermore, the electrostatic chuck is formed by depositing a conductive layer on an insulating base, depositing an aluminum layer on the conductive layer, and anodizing the aluminum layer.

Even further, the base of the electrostatic chuck is formed of ceramic.

Further, an insulating thin film is deposited on the surface of the alumite film.

The insulating thin film formed on the alumite film can be ceramic.

According to another aspect of the present invention, the object of the present invention is achieved by providing a method for manufacturing an electrostatic chuck for supporting on its upper surface a wafer to be subjected to processing, the electrostatic chuck having a surface for chucking wafer that is electrostatically bipolar, the method comprising forming plural conductive thin films on a surface of an insulating base; forming an aluminum layer on a surface of the plural conductive thin films; and forming an alumite film by anodizing a surface of the aluminum layer.

Furthermore, the above method for manufacturing an electrostatic chuck comprises forming an insulating ceramic film on a surface of the alumite film.

### BRIEF DESCRIPTION OF THE DRAWINGS

FIG. 1 is a perspective view and a cross-sectional view of an electrostatic chuck according to one embodiment of the present invention;

FIG. 2 is a cross-sectional view showing an etching apparatus according to one embodiment of the present invention;

FIG. 3 is a cross-sectional view explaining the method for manufacturing an electrostatic chuck according to one embodiment of the present invention;

FIG. 4 is a cross-sectional view of an electrostatic chuck according to another embodiment of the present invention;

FIG. 5 is a cross-sectional view of an electrostatic chuck according to another embodiment of the present invention; and

FIG. 6 is a perspective view of an electrostatic chuck according to another embodiment of the present invention.

### DETAILED DESCRIPTION OF THE PREFERRED EMBODIMENT

The present invention solves the above-mentioned drawback of the chucking force being lost when plasma disappears by providing a bipolar electrostatic chuck. A bipolar electrostatic chuck generates chucking force regardless of whether plasma exists or not, and maintains its chucking force when plasma disappears. However, it is impossible to form a bipolar electrostatic chuck by applying the conventional method, that is, by providing anodization treatment to a single aluminum base. According to the conventional method, the aluminum base disposed directly below the chucking surface is monopolar, so it is impossible to form a bipolar chucking surface. Therefore, the present invention provides a plurality of electrically isolated aluminum films on an insulated base, and anodizes these aluminum films, thereby creating a bipolar electrostatic chuck.

On the other hand, the present invention solves the drawback of the deterioration of electrical or mechanical soundness of the alumite film by forming the above-mentioned insulated base with ceramic. If the thermal expansion coefficient of the base is substantially equal to the thermal expansion coefficient of alumite, the expansion and shrinkage caused by temperature change is uniformized throughout the whole electrostatic chuck body, and thermal stress generated near the interface between alumite and aluminum is minimized. By providing an insulating coating such as a ceramic coating on the alumite surface, the reliability of the chucking surface is further improved.

The preferred embodiment of the present invention will now be explained in detail with reference to the drawings.

### Embodiment 1

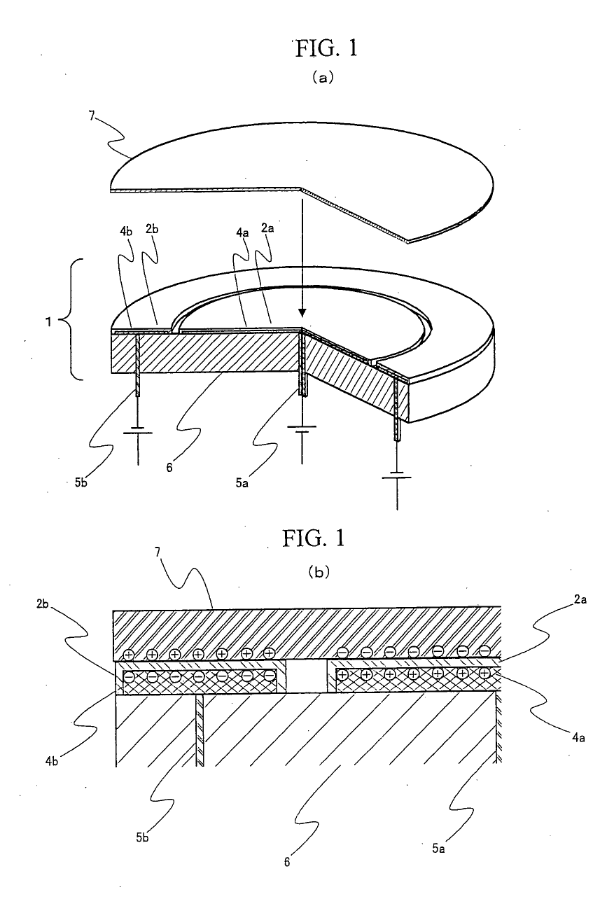

FIG. 1 is a cross-sectional view showing the simplified structure of an electrostatic chuck on which a wafer is mounted according to a first embodiment of a semiconductor processing apparatus of the present invention. An electrostatic chuck 1 shown in sectional view in FIG. 1 is used to mainly attract a wafer 7 and to subject the wafer to processing. The structure of the electrostatic chuck according to the present invention and the method for using the same will be illustrated hereafter.

The basic structure of the electrostatic chuck 1 according to the present invention comprises a base 6, conductive thin films 4a and 4b, alumite films 2a and 2b, and power feed wirings 5a and 5b. The base 6 is an insulator, and on the upper surface of the base, alumite films 2a and 2b are disposed via conductive thin films 4a and 4b. In the base 6 are disposed conductive power feed wirings 5a and 5b, which pass through the base 6, each having one end connected to conductive thin films 4a and 4b, respectively. The other end of the power feed wirings 5a and 5b are connected to DC power sources for electrostatic chuck, the wirings capable of providing independent potentials to the conductive thin films 4a and 4b.

Next, the steps for chucking the wafer 7 onto the electrostatic chuck 1 according to the present embodiment will be explained. At first, the wafer 7 is transferred using a wafer transfer means not shown, which is positioned so that its outer circumference substantially corresponds to the outer circumference of the electrostatic chuck 1, before it is mounted on the electrostatic chuck 1. Next, as illustrated in FIG. 1(b), power feed wirings 5a and 5b provide potentials having a mutually reversed polarity to the conductive thin films 4a and 4b, respectively. For example, if a positive electric charge is applied to the conductive thin film 4a and a negative charge is applied to film 4b, as illustrated in FIG. 1(b), the electric charge on the surface of the wafer 7 moves, and creates a force by the positive/negative charge at the conductive thin films 4a and 4b being attracted to the negative/positive charge at the surface of the wafer 7, which is so-called a Coulomb force, by which the wafer 7 is attracted to the electrostatic chuck 1.

While the wafer 7 is chucked to the electrostatic chuck 1, the wafer 7 is subjected to the desired plasma processing. After completing the plasma processing, when it is necessary to remove the wafer 7 from the electrostatic chuck 1, the potentials applied to the conductive thin films 4a and 4b are returned to substantially zero so that the distribution of electric charges on the wafer surface becomes leveled.

No attraction force occurs by simply providing a substantially equal potential of the same polarity to the conductive thin films 4a and 4b, but if the potential of the wafer and the potential of the conductive thin films 4a and 4b differ greatly, a Coulomb force is generated, by which the wafer is attracted to the electrostatic chuck.

Next, the preferred example of the plasma processing apparatus of the present invention will be explained by taking an etching process as the example of the plasma processing performed by the apparatus, which is one of the most important steps in semiconductor fabrication.

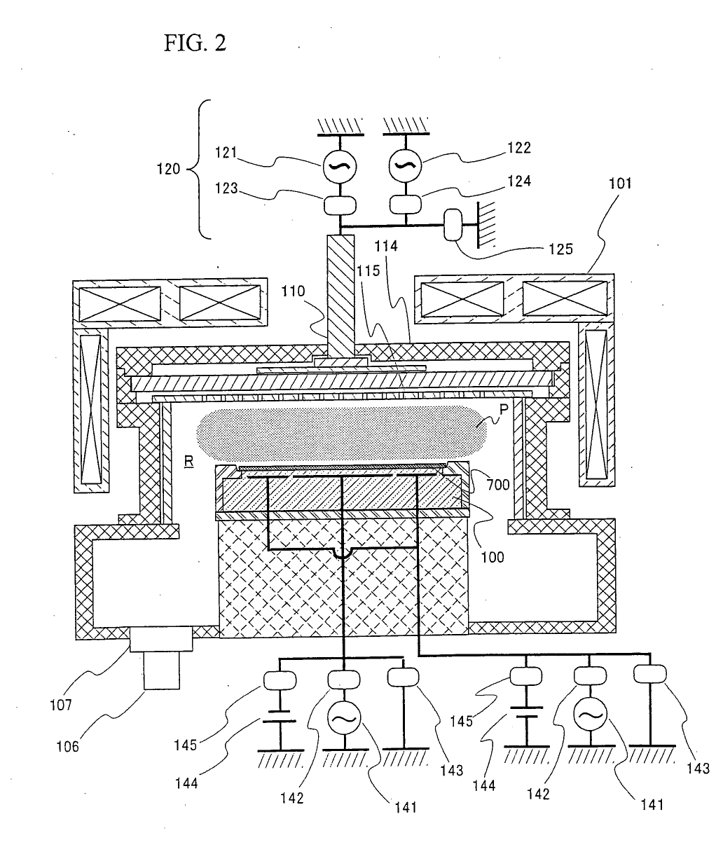

The outline of an etching apparatus utilized in the present embodiment is shown in FIG. 2. In FIG. 2, the processing chamber R is a vacuum vessel capable of maintaining pressure in the order of 1/10000 Pa. On the upper portion of the chamber is disposed an antenna 110 for radiating electromagnetic waves, and on the lower area is disposed an electrostatic chuck 100 for holding and supporting a sample 700 such as a wafer. The antenna 110 and the electrostatic chuck 100 are disposed in parallel and opposed to one another. A magnetic field generating means 101 comprising for example an electromagnetic coil and a yoke is disposed so as to surround the processing chamber R. By the interaction between the electromagnetic waves radiated through the antenna and the magnetic field created by the magnetic field generating means 101, the process gas introduced to the interior of the processing chamber is turned into plasma, generating a plasma P for processing the wafer 700.

On the other hand, the processing chamber R is evacuated via an evacuator 106, and pressure within the chamber is controlled by a pressure control means 107. The processing pressure is adjusted within the range of 0.1 Pa to 10 Pa. The antenna 110 is supported by a housing 114 constituting a portion of the vacuum vessel. Processing gas for etching the wafer and depositing a film thereto is supplied from a gas supply means with a predetermined flow rate and mixture ratio, which is supplied to the processing chamber R with a controlled distribution.

To the antenna 110 are connected an antenna power source 121 and an antenna bias power source 122 via a matching circuit/filter system 123 and 124, respectively, which constitute an antenna power source 120. The antenna power source 120 is connected to an earth via a filter 125. The antenna power source 121 supplies power in the UHF band frequency ranging from 300 MHz to 1 GHz. In the present embodiment, the frequency of the antenna power source 121 is 450 MHz. On the other hand, the antenna bias power source 122 applies bias power to the antenna 110 having a frequency range in the order of 10 kHz to the order of 10 MHz. In the present embodiment, this frequency is set to 13.56 MHz.

An electrostatic chuck 100 is provided to the lower portion of the processing chamber R where it is opposed to the antenna 110. The electrostatic chuck 100 is connected to a bias power source 141 supplying bias power in the range of 200 kHz to 13.56 MHz, for example, via a matching circuit and a filter system 142 through which the bias applied to the sample 700 is controlled, which is also connected to an earth via a filter 143. In the present embodiment, the frequency of the bias power source 141 is set to 400 kHz.

On the upper surface or sample mounting surface of the electrostatic chuck 100 is mounted a sample 700 such as a wafer. When etching a wafer 700 using the plasma etching apparatus according to the present embodiment, a DC voltage in the order of a few hundred V to a few kV is applied from the DC power source 144 and filter 145 for electrostatic chuck, by which the Coulomb force is generated. The electrostatic chuck 100 is controlled to have a determined surface temperature by a temperature control means not shown. Inert gas, such as helium gas, is supplied with predetermined flow rate and pressure to the space formed between the surface of the electrostatic chuck 100 and the back surface of the wafer 700, by which the thermal conductivity to the wafer 700 is increased. Thereby, the surface temperature of the wafer 700 can be controlled accurately with in a temperature range of 20° C. to 110° C.

The plasma etching apparatus according to the present embodiment is formed as explained above. Now, the actual process for etching an object, such as silicon, using the present plasma etching apparatus will be explained.

According to FIG. 2, the wafer 700 being the object of processing is transferred into the processing chamber R via a wafer transfer mechanism not shown, where it is mounted onto and chucked to the electrostatic chuck 100. The height of the electrostatic chuck 100 is adjusted if necessary, and a predetermined gap is set. Thereafter, gases required for etching the wafer 700, such as chlorine, hydrogen bromide and oxygen, are supplied from a gas supply means not shown, which is provided to the processing chamber R with predetermined flow rate and mixture. Simultaneously, the interior of the processing chamber R is adjusted to a predetermined processing pressure via an evacuator 106 and a pressure control means 107. Next, the antenna power source 121 supplies 450 MHz power to the antenna 110 so that electromagnetic waves are radiated through the antenna 110. The electromagnetic waves interact with the substantially horizontal, 160 gauss magnetic field (electron cyclotron resonance field intensity corresponding to 450 MHz) formed in the processing chamber R by a magnetic field generation means 101, and thereby, a plasma P is generated within the processing chamber R, dissociating the processing gas and generating ions and radicals. The antenna bias power from the antenna bias power source 122 and the bias power from the lower electrode bias power source 141 are utilized to control the composition ratio of ions and radicals within the plasma or the energy, while subjecting the wafer 700 to the etching process. When the etching process is completed, the supply of electric power, magnetic field and processing gas are stopped and etching is terminated.

The method for transferring the wafer 700 when the etching is terminated will now be explained. As mentioned before, in order to reduce the chucking force between the wafer and the electrostatic chuck, the DC voltage applied to the conductive thin films 4a and 4b shown in FIG. 1 should be blocked to reduce the potential difference between the conductive thin films 4a and 4b. In other words, when the potential difference between conductive thin films 4a and 4b is substantially zero, the wafer 700 can be detached from the alumite layers 2a and 2b. The detached wafer 700 is transferred to a next process via a transfer mechanism not shown.

However, there are cases where the wafer chucking force remains and prevents the wafer from being detached easily even when the potential difference between thin films 4a and 4b is substantially zero. This is because when the wafer 700 has sufficient conductivity, the electric charges accumulated in the alumite layers 2a and 2b are not neutralized. When the wafer is detached forcibly by a wafer detachment mechanism without sufficiently reducing the chucking force between the wafer 700 and the electrostatic chuck, the detached wafer 700 may pop up. Such risk can be avoided by applying voltages having reversed polarities as those applied during chucking to the conductive thin films 4a and 4b to thereby neutralize the accumulated charges, before using the wafer detachment mechanism.

### Embodiment 2

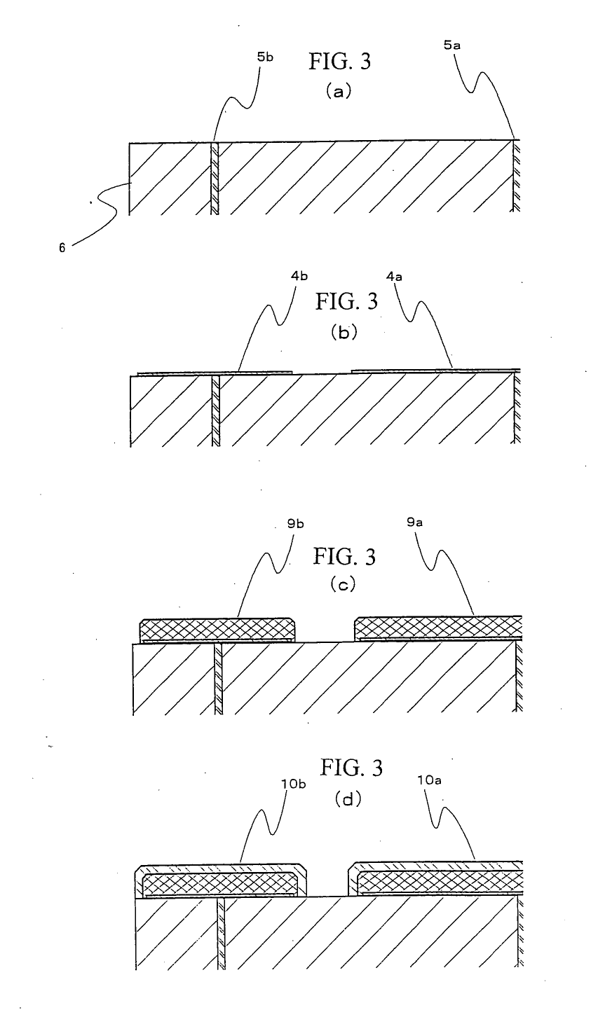

Now, a preferred embodiment for manufacturing the electrostatic chuck according to the present invention will be explained in detail. According to the present embodiment, as shown in FIG. 3(a), power feed wirings 5a and 5b are passed through and fixed to the predetermined locations in the base 6, which are then processed so that no gap is formed between the through-holes of the base 6 and the wirings, and the surface of the base 6 and the ends of the power feed wirings 5a and 5b are planarized. According to the present embodiment, the material of the base 6 is alumina, but other insulating materials such as ceramics like aluminum nitride and silicon carbide, and quarts. On the other hand, the material of power feed wirings 5a and 5b in the present embodiment is tungsten, but other conductive materials can be used to achieve the object of the invention.

Next, as shown in FIG. 3(b), conductive thin films 4a and 4b are disposed to have the desired shape on the base 6. In the present embodiment, the films 4a and 4b are formed by baking molybdenum—manganese alloy, but other conductive thin films such as sputtered films and plated films of various metals can also be used to achieve the object of the invention. The conductive thin films 4a and 4b are disposed so that each has a power feed wiring 5a or 5b electrically connected thereto.

Next, as shown in FIG. 3(c), aluminum layers 9a and 9b are formed on top of the conductive thin films 4a and 4b, which are then planarized. According to the present embodiment, the aluminum layers are disposed by brazing, but other methods such as sputtering, plating and compression bonding can also be applied to achieve the present object.

The aluminum layers 9a and 9b each have a thickness of approximately 100 micrometers. The planar shapes of the aluminum layers 9a and 9b can be a concentric ring and circle, as shown in FIG. 1, or they can be two semicircles. They can also be comb-shaped, according to which the apparatus can generate chucking force for an insulator such as bare glass. The surfaces of the aluminum layers 9a and 9b are finished so that they have a center line average roughness of 0.2 micrometers or smaller. Further, the corners of the aluminum layers are chamfered. Chamfering is important to prevent cracks from being formed to the corners of the alumite film after the following alumite processing. The shapes of the corners of the aluminum layers can also be rounded off.

Thereafter, as illustrated in FIG. 3(d), the surfaces of the aluminum layers 9a and 9b are anodized. The anodized aluminum layer (alumite layer) is grown by applying voltage via power feed wirings 5a and 5b to the aluminum layers 9a and 9b in an oxalic acid solution. When the alumite films 10a and 10b shown in FIG. 3(d) reaches a thickness of 50 micrometers, the process is terminated. By this process alone, however, very fine cracks formed in the thickness direction exist within the alumite films 10a and 10b, so in order to seal these cracks, the formed alumite films are exposed to high-temperature vapor.

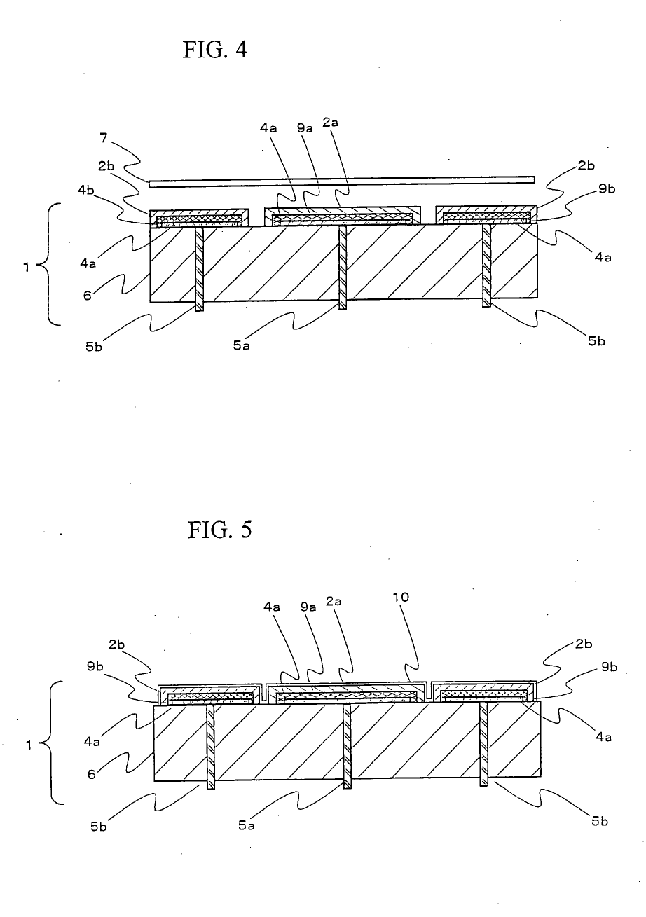

The cross-section of the electrostatic chuck 1 as manufactured according to the above-explained method is shown schematically in FIG. 4. When a silicon wafer 7 is mounted on the manufactured electrostatic chuck 1 and DC voltages of +500V and −500V are respectively applied to the power feed wirings 5a and 5b, the wafer 7 is chucked to the electrostatic chuck. The generation of a chucking force of over 4 kPa was confirmed by pulling the wafer 7 toward the perpendicular direction against the chucking surface of the electrostatic chuck 1. Thus, it is confirmed that according to the method disclosed in the present embodiment, a bipolar electrostatic chuck capable of providing a sufficient chucking performance is manufactured.

### Embodiment 3

Now, another preferred embodiment of the electrostatic chuck according to the present invention will be explained. FIG. 5 shows a schematic drawing of an electrostatic chuck according to the present embodiment. In the present embodiment, an insulating film 10 is further deposited on the surfaces of alumite films 2a and 2b. The reason for depositing this film is as follows. As mentioned in the description of embodiment 2, very fine cracks are inevitably formed in the alumite films. Therefore, it is extremely difficult to eliminate the cracks within the alumite film. However, with many cracks formed within the alumite films, the withstand voltage of the alumite films or the chucking films is deteriorated, and the performance of the electrostatic chuck is thereby degraded.

According to embodiment 2, in order to improve the withstand voltage of the alumite film, the alumite films 2a and 2b are exposed to vapor after deposition so that apertures are sealed. This treatment is simple and effective to a certain extent, but in some cases the effect is not satisfactory. Therefore, by depositing an insulating film 10 on the surface of the alumite films as according to the present embodiment, the withstand voltage of the chucking film can be improved, and the problems caused by breakdown can be reduced significantly. Moreover, higher voltages can be applied to the power feed wirings 5a and 5b, thus a greater chucking force can be obtained. Furthermore, the reliability of the electrostatic chuck is still maintained after long period of use or after repeated change of temperature.

According to the present embodiment, an aluminum CVD (chemical vapor deposition) film is used as the insulating film, and the thickness of the film is 5 micrometers. According to this CVD process, the average withstand voltage of the chucking film is improved to approximately 5 kV from the former 3 kV. On the other hand, chucking force is not changed greatly by this CVD process. In conclusion, it has become clear that the deposition of an insulating film on the surface of the alumite films is extremely effective in improving the reliability of the present electrostatic chuck.

### Embodiment 4

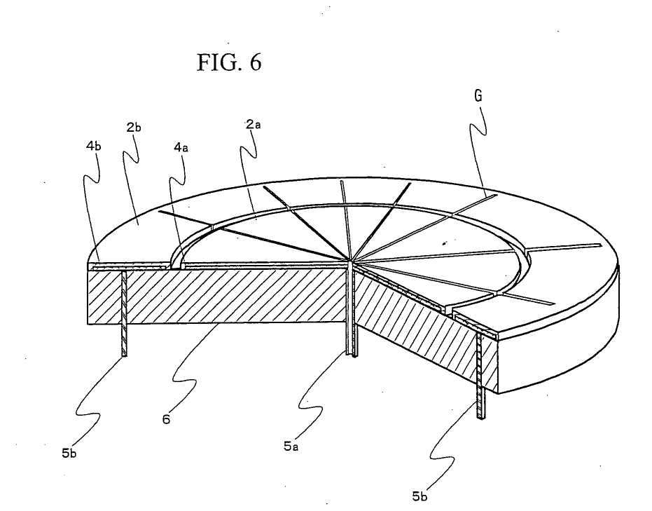

In some cases, it is necessary to fill gas such as helium having a predetermined pressure to the space formed between the wafer and the chucking film in order to improve the heat transmission rate of the wafer and film to thereby control the wafer temperature. According to this embodiment, as shown in FIG. 6, the surface of the chucking film is provided with grooves G and treated to have a certain roughness, so that the dispersion of pressure of the gas between the wafer and film is effectively reduced. In this case, a sealing structure must be disposed on the outer circumference portion of the electrostatic chuck so as to prevent gas from leaking out into the vacuum vessel from the back of the wafer. According to the present embodiment, the grooves formed to the chucking surface are designed so that they do not reach the outer circumference of the wafer holder.

In actual application of this embodiment, the shapes of the aluminum films 9a and 9b of FIG. 3 should be appropriately formed in advance so as to prevent gas from leaking from the outer circumference of the alumina films.

While embodiments 1 through 4 have been chosen to illustrate the present invention, various changes and modifications can be made without departing from the scope of the invention as defined in the appended claims.

According to the present invention, a bipolar electrostatic chuck that is easy to handle and is highly reliable from the point of view of withstand voltage etc. can be manufactured at a low cost, and the electrostatic chuck can be applied to form an improved plasma processing apparatus.

What is claimed is:

1. A method for manufacturing an electrostatic chuck for supporting on its upper surface a wafer to be subjected to processing, the electrostatic chuck having a surface for chucking wafer that is electrostatically bipolar, the method comprising:
forming plural conductive thin films on a surface of an insulating base;
forming an aluminum layer on a surface of said plural conductive thin films; and
forming an alumite film by anodizing a surface of said aluminum layer.

2. A method for manufacturing an electrostatic chuck according to claim 1, further comprising forming an insulating ceramic film on a surface of said alumite film.
